(19) United States
(12) Patent Application Publication
(10) Pub. No.: US 2006/0145310 A1
(43) Pub. Date: Jul. 6, 2006

(54) Device for detecting RF power and fabrication method thereof

(75) Inventors: Jae-Hyoung Park, Seoul (KR); Hee-Chul Lee, Daejeon (KR)

Correspondence Address: JONATHAN Y. KANG, ESQ.;LEE, HONG, DEGERMAN, KANG & SCHMADEKA, 14th Floor, 801 S. Figueroa Street, Los Angeles, CA, 90017, US

(73) Assignee: LG Electronics Inc.

(21) Appl. No.: 11/327,533

(22) Filed: Jan. 5, 2006

(30) Foreign Application Priority Data
Jan. 6, 2005 (KR) 10-2005-0001353

(51) Int. Cl. H01L 29/40

(52) U.S. Cl. 257/664

(57) ABSTRACT

Disclosed herein is a low-cost low power-consumed RF power detecting device used as a core component necessary for intelligence, miniaturization and downpricing of a wireless communication system, and a fabrication method thereof. The RF power detecting device according to the present invention comprises: an upper substrate including a signal transmission line for transmitting a predetermined RF signal therethrough; a sensor section for detecting power of the RF signal transmitted through the signal transmission line; and a lower substrate for supporting the sensor section. The method of fabricating the RF power detecting device comprises the steps of: forming a sensor section for detecting power of an RF signal on a lower substrate; patterning a signal transmission line on the underside of an upper substrate; and coupling the upper substrate and the lower substrate to each other.

Pursuant to 35 U.S.C. § 119(a), this application claims the benefit of earlier filing date and right of priority to Korean Patent Application No(s). 10-2005-0001353 filed on Jan. 6, 2005, which is hereby incorporated by reference herein in their entirety.

### BACKGROUND OF THE INVENTION

1. Field of the Invention

The present invention relates to a low-cost low power-consumed RF power detector used as a core component necessary for intelligence, miniaturization and downpricing of a wireless communication system, and a fabrication method thereof.

2. Background of the Related Art

Currently, with the development of information communication technology, researches are being actively performed on compactness, lightness and advancement of performance of elements. Particularly, an RF power sensor is a core component that performs an important role in controlling the magnitude of an RF signal output from a wireless communication device and the gain of a power amplifier with input/output stages for the wireless communication device. Nowadays, many efforts are concentrated on the development of an RF power sensor for satisfying the specifications required in satellite communication antennas, signal control systems, mobile communication terminals, etc. Specifically, there is an urgent need for miniaturization and performance improvement of an RF power sensor as the core component for application of high frequency band and multiband

An existing power sensor employs a thermistor, thermocouple, or a diode as an important part thereof. Such a conventional power sensor consumes power by itself at a power sensing step, and characteristic variation according to a change in ambient temperature has a great effect on the performance of elements. In addition, first of all, there is urgently needed performance improvement of the sensor in the environment where linearity of elements is required.

FIG. 1 is a view illustrating an example of a conventional RF power sensor employing a diode among existing power sensors using a thermostor, a thermocouple or a diode. As shown in FIG. 1, an RF signal which are rectified by a diode is detected through the coupling between the diode and a signal transmission line at an end of the signal transmission line so as to detect RF power. This scheme is accompanied by consumption of an RF signal transmitted at the time of detecting RF power, and hence makes it difficult to re-use the transmitted RF power signal. Therefore, such a power sensor has a demerit in that there is needed a circuit designed in consideration of generation of the RF signal for detection of power. Further, according to this configuration, it is not easy to reduce the size of an element. Such a problem is also caused even in case of a power sensor employing a thermostor or a thermocouple.

According to the arrangement of such a conventional power sensor, since the use of a power supply for driving the sensor increases consumption of power, the lifespan of a battery is shortened and stability of performance according to an ambient temperature environment may be problematic.

### SUMMARY OF THE INVENTION

Accordingly, the present invention has been made to overcome the above-mentioned problems and limitations occurring in the prior art, and it is an object of the present invention to provide a device for detecting an RF power, which has high linearity and high characteristic stability according to an ambient temperature without loss of an RF signal being transmitted.

Another object of the present invention is to a device for detecting an RF power, which can be implemented with small-sized elements and can improve reliability and yield of the elements, thereby making it possible to easily be applied to mobile communication terminals.

Yet another object of the present invention is to a device for detecting an RF power, which enables easy electrical connection by forming connection holes (via-holes) on an upper substrate upon the packaging of the device, thereby minimizing loss of an RF signal and reflective effect due to signal interference, an additional connection line or the like to improve the characteristic of the sensor.

A further object of the present invention is to a device for detecting an RF power, which enables a package process of a wafer unit and facilitates integration with other RF circuits so that it is greatly effective in entire transmission characteristics of an RF signal.

A still further object of the present invention is to a method of fabricating the RF power detecting device.

To accomplish the above objects, according to one aspect of the present invention, there is provided a device for detecting RF power comprising: an upper substrate including a signal transmission line for transmitting a predetermined RF signal therethrough; a sensor section for detecting power of the RF signal transmitted through the signal transmission line; and a lower substrate for supporting the sensor section.

According to another aspect of the present invention, there is also provided a method of fabricating an RF power detecting device, comprising the steps of: forming a sensor section for detecting power of an RF signal on a lower substrate; patterning a signal transmission line on the underside of an upper substrate; and coupling the upper substrate and the lower substrate to each other.

### BRIEF DESCRIPTION OF THE DRAWINGS

The above and other objects, features and advantages of the present invention will be become more apparent from the following detailed description of the preferred embodiments of the invention in conjunction with the accompanying drawings, in which:

FIG. 1 is a view illustrating the construction of a conventional RF power sensor using a diode according to the prior art;

FIG. 2 is a schematic perspective view illustrating a piezoelectric type RF power detecting device according to the present invention;

FIG. 3 is a cross-sectional diagrammatic view illustrating a piezoelectric type RF power detecting device which is packaged according to the present invention;

FIG. 4 is a view illustrating the operation principle of a sensor section of a piezoelectric type RF power detecting device according to the present invention;

FIG. 5 is a view illustrating an example of the fabrication procedure of a lower substrate for a piezoelectric type RF power detecting device according to the present invention;

FIG. 6 is a view illustrating a first fabrication embodiment of a depression provided at a lower substrate for a piezoelectric type RF power detecting device according to the present invention;

FIG. 7 is a view illustrating a second fabrication embodiment of a depression provided at a lower substrate for a piezoelectric type RF power detecting device according to the present invention; and

FIG. 8 is a view illustrating an example of the fabrication procedure of an upper substrate for a piezoelectric type RF power detecting device according to the present invention in which the upper substrate and the lower substrate are bonded to each other.

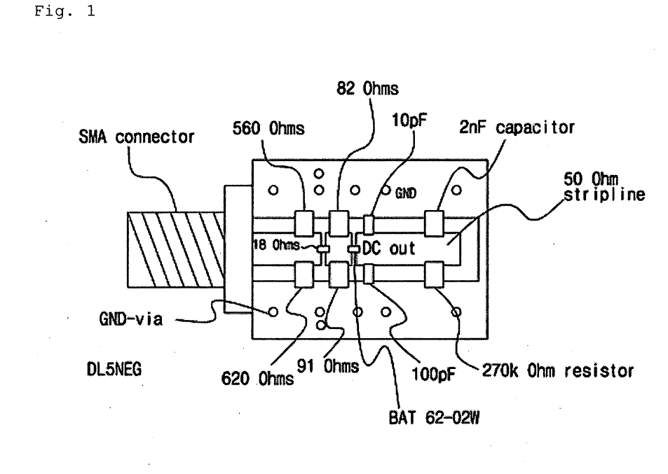

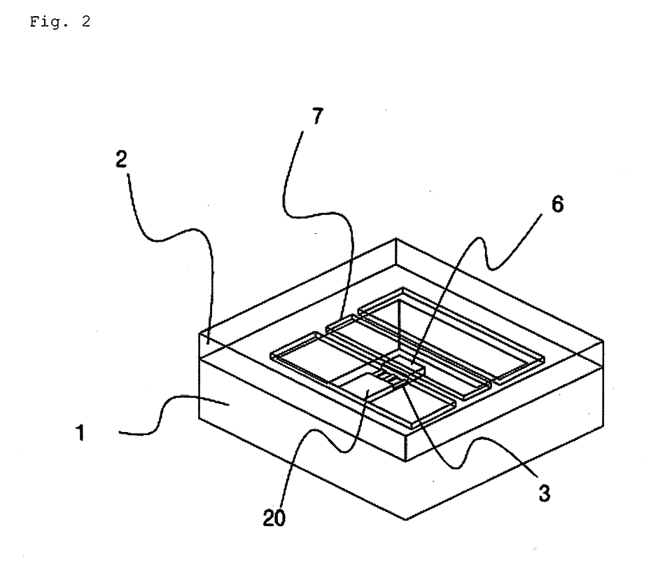

### DETAILED DESCRIPTION OF THE PREFERRED EMBODIMENT

Reference will now be made in detail to the preferred embodiment of the present invention with reference to the attached drawings.

Throughout the drawings, it is noted that the same reference numerals or letters will be used to designate like or equivalent elements having the same function. The detailed descriptions on known function and construction unnecessarily obscuring the subject matter of the present invention will be avoided hereinafter.

The present invention provides an RF power detecting device and a fabrication method thereof, which are intended to address and resolve the problems of a conventional power sensor.

According to the present invention, application of an RF Micro Electro-Mechanical System (MEMS) technology substitutes electrical elements by mechanically movable structures, so that power is not consumed at an RF power detection step, and hence an RF signal being detected can be used immediately. Moreover, the linearity of elements can be improved by utilizing the mechanically movable structure. The RF power detecting device according to the present invention implemented with the RF MEMS technology has a merit in that since it is insensitive to temperature characteristics, stability of performance according to an ambient temperature environment can be secured. Simultaneously, the inventive RF power detecting device can be applied to a wireless communication system through its miniaturization, and can contribute to miniaturization and cost reduction of a communication terminal.

The device for detecting RF power according to the present invention comprising: an upper substrate including a signal transmission line for transmitting a predetermined RF signal therethrough; a sensor section for detecting power of the RF signal transmitted through the signal transmission line; and a lower substrate for supporting the sensor section.

The method of fabricating the RF power detecting device according to the present invention comprising the steps of: forming a sensor section for detecting power of an RF signal on a lower substrate; patterning a signal transmission line on the underside of an upper substrate; and coupling the upper substrate and the lower substrate to each other.

FIG. 2 is a schematic perspective view illustrating a piezoelectric type RF power detecting device according to the present invention.

Referring to FIG. 2, in this embodiment, an RF power detecting device enables a piezoelectric type detection of power of an RF signal, and comprises a lower substrate 1 including a sensor section that generates displacement in response to power of an RF signal being transmitted and an upper substrate 2 including a signal transmission line.

In the present invention, elements including the entire power sensor are packaged by means of an eutectic bonding between substrates, simultaneously together with the sensor section, thereby implementing packaging of a wafer unit that has an excellent characteristic of an RF power sensor and ensures hermetic packaging and superior mechanical strength.

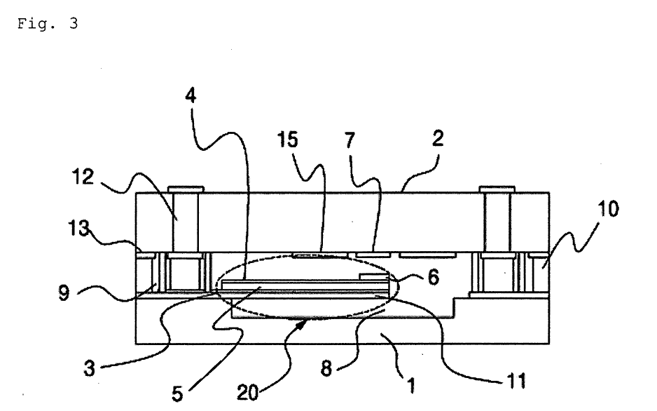

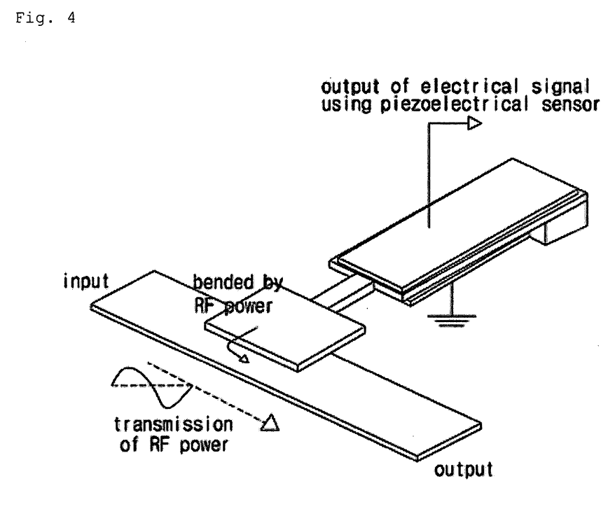

FIG. 3 is a cross-sectional diagrammatic view illustrating a piezoelectric type RF power detecting device which is packaged according to the present invention.

Referring to FIG. 3, the sensor section of the lower substrate 1 includes a lower electrode 3 for detecting displacement generated in response to power of an RF signal, an upper electrode 4 disposed above the lower electrode 3, a piezoelectric thin film 5 formed between the lower electrode 3 and the upper electrode 4, and a movable member 6 disposed on the upper electrode 4 and adapted to be applied with a force by the RF power. The upper electrode 4 is connected to a ground line 15 of the signal transmission line 7 so that displacement occurs in response to power of an RF signal transmitted through the signal transmission line 7 of the upper substrate 2.

The sensor section 20 of the lower substrate 2 operated in a piezoelectric manner is fabricated in such a fashion that it floats above a depression 8 formed on the lower substrate 1 by using the Micro Electro-Mechanical System (MEMS). Such a structure further facilitates packaging of internal elements through bonding between the lower substrate and the upper substrate.

The RF signal transmission line 7 is patterned on the underside of the upper substrate 2, and is electrically connected to the opposite side to the underside of the upper substrate through a connection hole, i.e., a via-hole. The bonding between the upper substrate 2 and the lower substrate 1 is carried out by means of eutectic bonding, and a diffusion preventing layer is preferably interposed between the upper substrate 2 and the lower substrate 1 to maintain a spacing between the signal transmission line 7 of the upper substrate 2 and the sensor section of the lower substrate 1.

Upon the bonding between the upper substrate 2 and the lower substrate 1, an electrode pad for driving the sensor section of the lower substrate is electrically connected to the opposite side to the underside of the upper substrate through a connection hole, i.e., a via-hole.

The sensor section of the lower substrate 1 is manufactured in such a fashion that it floats above a depression 8 formed on the lower substrate 1 by using the MEMS, and shares a ground line of the signal transmission line 7 of the upper substrate 2, so that displacement occurs in response to transmission power of an RF signal transmitted through the signal transmission line 7. That is, as power of the RF signal transmitted to the signal transmission line 7 increases, the movable member 6 is moved toward the signal transmission line 7 so that the spacing between the signal transmission line 7 and the movable member 6 decreases. Such displacement causes a piezoelectric thin film 5 to generate an electrical signal which is in turn detected between the lower electrode 3 and the upper electrode 4 to thereby detect power of the RF signal being transmitted through the signal transmission line.

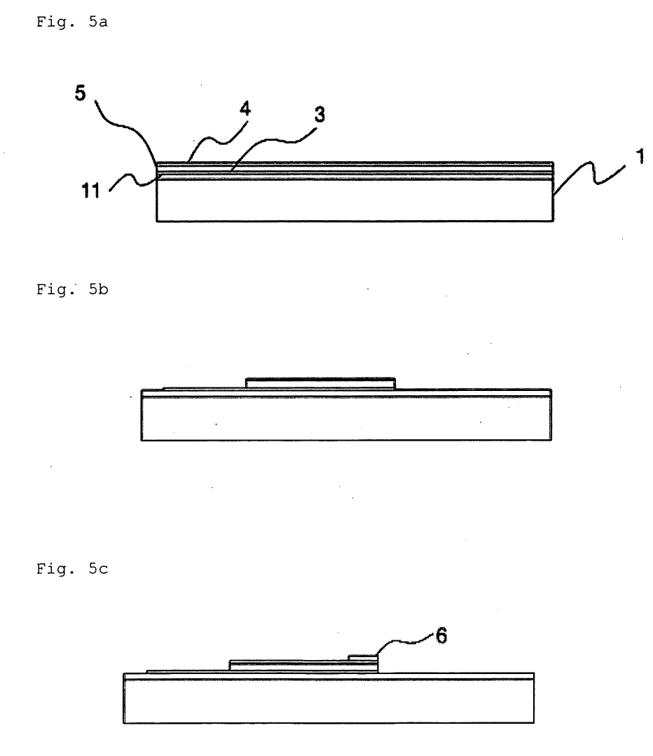

In FIG. 4, such a principle for detecting the RF power is diagrammatically shown briefly.

As shown in FIG. 4, when an RF signal is transmitted through the signal transmission line 7, a force is exerted to the sensor section that floats depending on the magnitude of the RF signal. At this time, the force exerted to the sensor section can be expressed in the following equation (1).

$${F}_{e} = \frac{{CV}_{rms}^{2}}{2 d} \qquad ( 1 )$$

where Fₑ is a force applied to the floating movable member, C is a capacitance between the signal transmission line and the floating movable member of the sensor section, Vᵣₘₛ is an rms voltage of the RF signal being transmitted, and d is a distance between the signal transmission line and the floating movable member.

When the floating sensor section is applied with the force from the signal transmission line propagating the RF signal, it generates a displacement as follows:
F=kx (2)

where k is a spring constant of the floating sensor section, and x is a displacement of the movable member by the RF signal being transmitted.

Since this displacement is detected in a piezoelectric manner, power of the RF signal being transmitted through the signal transmission line 7 can be detected.

The upper substrate 2 serves as a support substrate of the signal transmission line 7, and has a structure for packaging the sensor section of the lower substrate 2. The signal transmission line 7 is electrically connected to the outside of the packaging through the connection hole, i.e., the via-hole of the upper substrate 2, and maintains a uniform spacing together with the sensor section through the bonding between the upper substrate 2 and the lower substrate 1. The lower electrode 3 for detecting a displacement of the sensor section of the lower is also electrically connected to the outside of the packaging through the connection hole.

The upper substrate 2 and the lower substrate 1 can be bonded to each other by means of eutectic bonding. The spacing between the movable member 6 constituting the sensor section and the signal transmission line 7 is uniformly maintained to secure sufficient isolation of the sensor section and reduce a loss of the RF signal being transmitted. Upon the bonding between the upper substrate 2 and the lower substrate 1, the spacing therebetween can be adjusted by the support member 9. This support member 9 may be implemented in the form of a polymer spacer or/and a diffusion preventing film, and the spacing between the signal transmission line 7 and the sensor section of the lower substrate 1 may be adjusted depending on the thickness of the support member 9.

Such a structure is advantageous in that it enables the bonding and the fabrication of the entire wafer, so that a low-cost piezoelectric type RF power detecting device packaged in a wafer unit can be implemented.

The RF power detecting device according to the present invention can be applied as an indispensable component in next-generation mobile communication terminals.

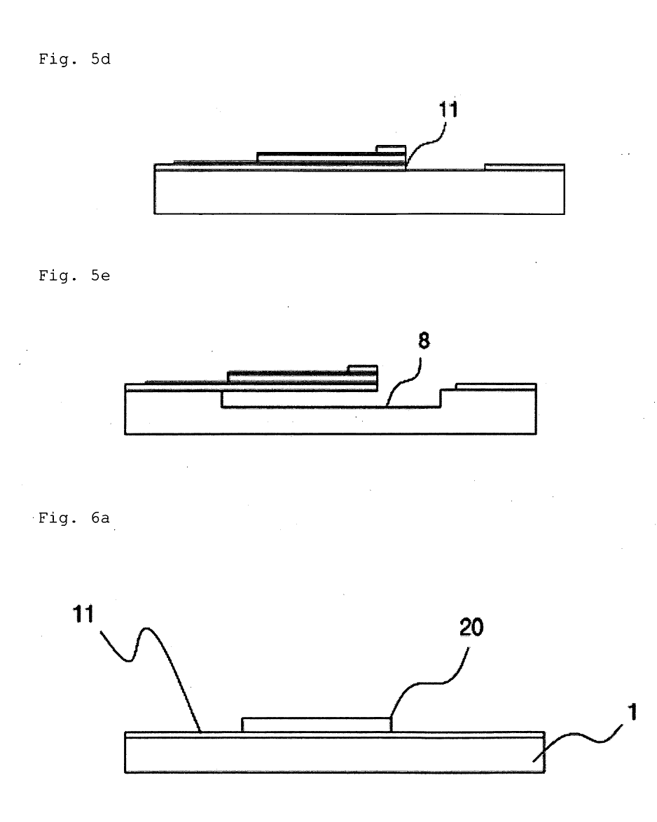

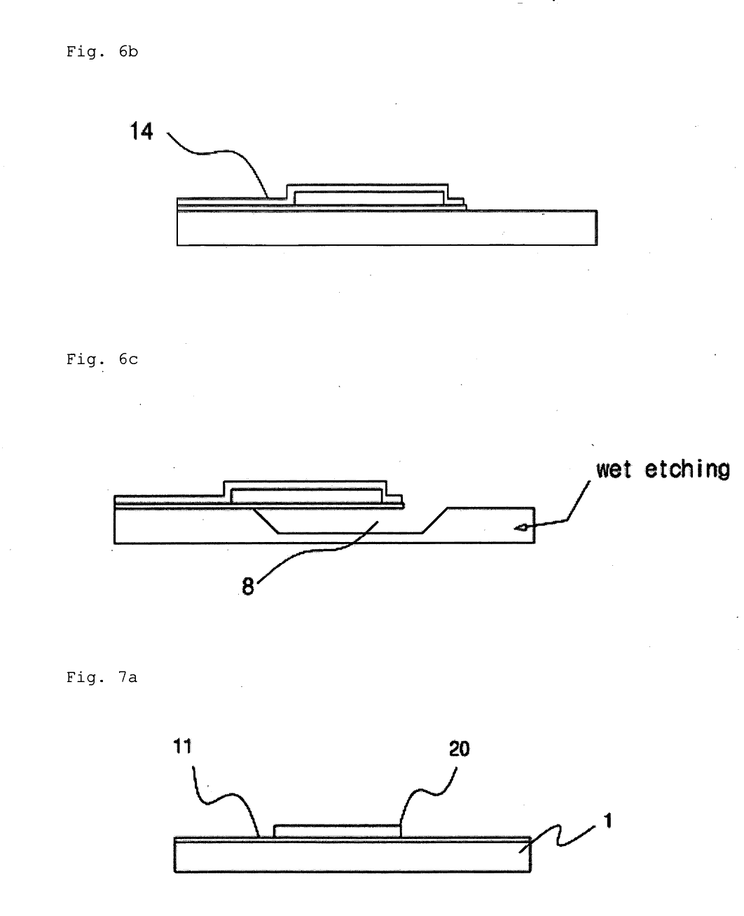

FIG. 5 is a view illustrating an example of the fabrication procedure of a lower substrate 1 for a piezoelectric type RF power detecting device according to the present invention.

As shown in FIG. 5(a), first, a silicon nitride 11 is deposited on a silicon lower substrate 1 by means of a low-pressure chemical vapor deposition (CVD) method, and a lower electrode layer (Ti/Pt) 3, a piezoelectric thin film layer 5 and an upper electrode layer (RuO₂) 4 are formed in the above order on a surface of the silicon nitride layer 1 for the sensor section to be formed.

Also, as shown in FIG. 5(b), the lower electrode layer (Ti/Pt) 3, the piezoelectric thin film layer 5 and the upper electrode layer (RuO₂) 4 are patterned and etched into a given shape. The sensor section is not necessarily limited to such a concrete shape as in this embodiment. After the etching process, as shown in FIG. 5c, the movable member 6 which is applied with a force below the signal transmission line, e.g., a metal plate is deposited on the etched upper electrode layer 4 and then is patterned into a given shape.

Thereafter, as shown in FIG. 5(d), the silicon nitride layer to be used as an insulation film-connecting structure is patterned and etched. After the etching of the silicon nitride has been completed, as shown in FIG. 5(e), the sensor section is protected and then the silicon layer surface positioned below the sensor section is subjected to etching so as to form a depression 9 on the silicon layer for allowing the sensor section structure to float thereabove.

Anisotropic etching characteristics according to direction of silicon can be used in order to allow the sensor section to float.

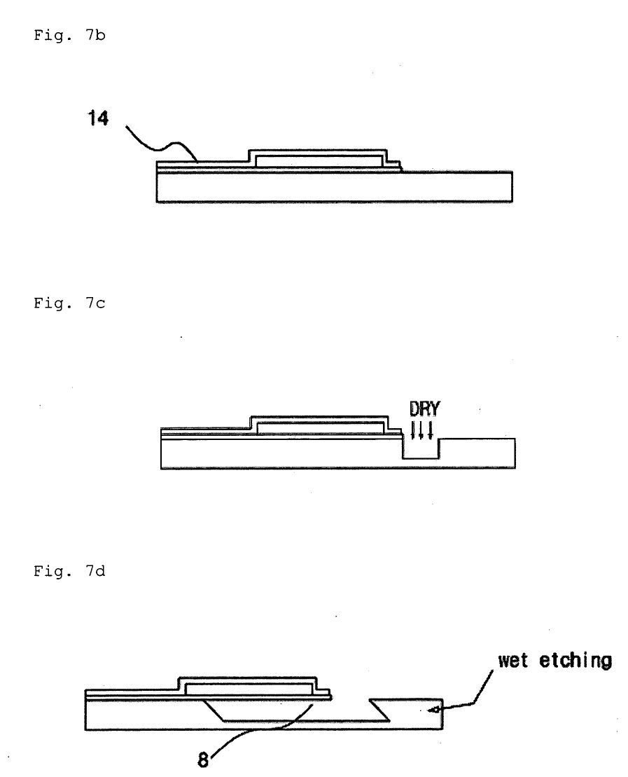

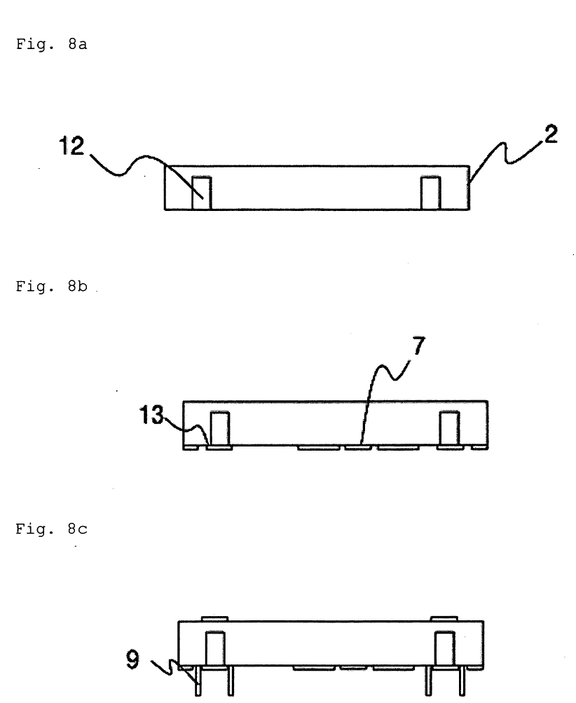

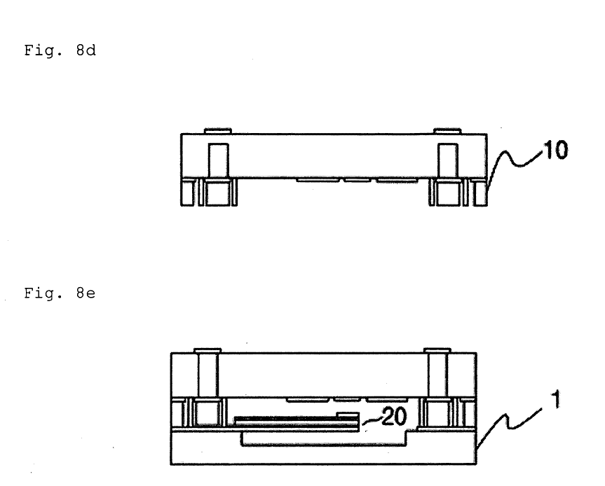

FIG. 6 is a diagrammatic cross-sectional view illustrating an embodiment of a process of forming a depression by using anisotropic etching of a silicon wafer upon the forming of the lower substrate.

As shown in FIG. 6, first, a film 14 for protecting the sensor section 20 is deposited and patterned on the sensor section 20. Afterwards, the silicon substrate is subjected to anisotropic etching of a wafer by using an etching solution for wet etching, for example, a KOH etching solution. As a result, a depression 8 is formed on the silicon substrate surface positioned below the sensor section, so that the sensor section 20 can float above the depression formed on the lower substrate.

Another embodiment of a process of forming a depression by using anisotropic etching of a silicon wafer is illustrated in FIG. 7.

FIG. 7 is a diagrammatic cross-sectional view illustrating another embodiment of a process forming a depression by using anisotropic etching of a silicon wafer.

As shown in FIG. 7, first, a film 14 for protecting the sensor section 20 is deposited and patterned on the sensor section 20. Afterwards, the silicon substrate region around the sensor section 20 is vertically etched by using anisotropic dry etching of a silicon wafer. The vertical etching is performed to secure a sufficient height required for the sensor section to float, and then the silicon substrate is subjected to anisotropic wet etching of a silicon wafer by using a KOH etching solution to form a depression 8 on the silicon substrate surface positioned below the sensor section, so that the sensor section 20 can float above the depression formed on the lower substrate.

Another embodiment of a process of forming a depression by using isotropic dry etching of a silicon wafer will be described below.

The process of forming a film for protecting the sensor section is the same as in the above two embodiments. After the protecting film has been formed, isotropic dry etching using silicon etching gas is employed instead of anisotropic wet etching of a silicon wafer. The silicon substrate region positioned below the sensor section is etched by the isotropic dry etching of a silicon wafer to form the depression on the silicon substrate surface, so that the sensor section can float above the depression formed on the silicon lower substrate. Such an isotropic etching method includes isotropic etching using XeF₂ gas, isotropic etching using SF₆ gas, etc.

FIG. 8 is a view illustrating an example of the fabrication procedure of an upper substrate for a piezoelectric type RF power detecting device according to the present invention in which the upper substrate and the lower substrate are bonded to each other.

Referring to FIG. 8(a), first, a silicon or glass wafer is processed so as to have a connection hole formed thereon for connecting the signal transmission line 7, the ground line, and the lower electrode of the sensor section to an external circuit therethrough. In case of the silicon wafer, the connection hole is formed on the silicon wafer by means of anisotropic wet or dry etching method. Also, in case of the glass wafer, the connection hole can be formed by means of sand blaster or laser cutting. The formed connection hole is filled with gold or copper having excellent electrical conductivity through an electroplating method to form a connection line 12, and then the electroplating structure protruding around the connection hole is flattened through chemical mechanical polishing (CMP).

Then, as shown in FIG. 8(b), CPW (Coplanar waveguide) transmission line 7 for transmitting a signal input from the outside therethrough is formed and patterned by means of electroplating or metal thin film deposition. Simultaneously, at this step, on the underside of the upper substrate 2 is formed an electrode pad 13 for allowing the upper substrate 2 and the lower electrode of the sensor section to be bonded to each other.

Subsequently, as shown in FIG. 8(c), a polymer spacer or/and a diffusion preventing film as a support member 9 is patterned. The polymer spacer acts to control the spacing between the upper substrate and the lower substrate upon the bonding between the substrates, so that the distance between the CPW transmission line 7 of the upper substrate and the sensor section of the upper substrate is determined depending on the height of the spacer. Such a distance determines isolation at an initial state of the sensor section, and simultaneously determines a displacement of the sensor section due to power of an RF signal being transmitted through the signal transmission line. Therefore, the distance between the upper and lower substrates becomes an important variable for sensitivity of power detection.

In case of using the diffusion preventing film, this film functions to prevent diffusion of substance used as bonding material toward the electrodes upon the eutectic bonding, so that a proper distance between the upper and lower substrates can be maintained.

As shown in FIG. 8(d), a bonding layer 10 used as bonding material for the upper and lower substrates is patterned. The bonding between the upper and lower substrates is carried out by eutectic bonding under the constant temperature and pressure. For the purpose of application of this bonding method, usable bonding material includes gold (Au), gold-tin alloy (AuSn), tin (Sn), etc.

Then, as shown in FIG. 8(e), the upper substrate and the lower substrate are bonded to each other under the condition of constant temperature and pressure. Since the edge of the bonding layer is formed around an RF power sensor circuit, elements are isolated from the outside by the bonding layer 10 upon the bonding between the upper and lower substrates. Through this process, hermetic packaging of the RF power detecting device can be implemented.

The metal bonding material used at the time of bonding the upper and lower substrates is liable to be diffused toward the electrodes by being melt under a bonding condition. In order to prevent this, a diffusion preventing film serving to obstruct the bonding material like a dam may be formed around the bonding material. Through this process, a process which can enhance uniformity and strength of packaging of a wafer unit can be implemented.

After the bonding between the upper and lower substrates has been compledted, as shown in FIG. 8e, the opposite surface of the upper substrate is processed by means of chemical mechanical polishing (CMP) until the electrode connection hole is exposed to the outside. On the underside of the upper substrate is formed an electrode pad for connecting the signal transmission line, the ground line, and the lower electrode of the sensor section to the external circuit, so that the RF power detecting device is finally fabricated.

As described above, according to the present invention, it is possible implement a device for detecting an RF power, which enables a package process of a wafer unit and has high linearity and high characteristic stability according to an ambient temperature without loss of an RF signal being transmitted.

In addition, the inventive RF power detecting device can be implemented with small-sized elements and can improve reliability and yield of the elements, thereby making it possible to easily be applied to mobile communication terminals.

Furthermore, the inventive RF power detecting device enables easy electrical connection by forming connection holes (via-holes) on an upper substrate upon the packaging of the device, thereby minimizing loss of an RF signal and reflective effect due to signal interference, an additional connection line or the like to improve the characteristic of the sensor. Moreover, the inventive RF power detecting device facilitates integration with other RF circuits so that it is greatly effective in entire transmission characteristics of an RF signal.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A device for detecting RF power comprising:
an upper substrate including a signal transmission line for transmitting a predetermined RF signal therethrough;
a sensor section for detecting power of the RF signal transmitted through the signal transmission line; and
a lower substrate for supporting the sensor section.

2. The device set forth in claim 1, wherein the sensor section detects the power of the RF signal in a piezoelectric manner.

3. The device set forth in claim 1, wherein the upper substrate comprises a via-hole formed thereon for allowing the signal transmission line to receive a signal from the outside.

4. The device set forth in claim 1, wherein the lower substrate has a given depression formed thereon in such a fashion as to be positioned under the sensor section so as to allow the sensor section to float in the space defined between the upper substrate and the lower substrate.

5. The device set forth in claim 1, wherein the sensor section comprises:
a movable member for generating displacement in response to the power of the RF signal;
a piezoelectric thin film for generating charges in proportion to the displacement of the movable member; and
an electrode for detecting the charges generated by piezoelectric thin film,
wherein the electrode includes a lower electrode and an upper electrode disposed above the lower electrode 3, and
wherein the movable member is disposed on the upper electrode and the piezoelectric thin film is interposed between the upper electrode and the lower electrode.

6. The device set forth in claim 5, wherein a force exerted to the movable member to generate the displacement is in proportional to a capacitance between the signal transmission line and the movable member and a voltage of the RF signal, and is inverse proportional to a distance between the signal transmission line and the movable member.

7. The device set forth in claim 5, wherein the movable member generates the displacement in proportional to the power of the RF signal.

8. The device set forth in claim 1, wherein the upper substrate further includes a ground section of the signal transmission line.

9. The device set forth in claim 8, wherein the ground section is connected to the sensor section.

10. The device set forth in claim 1, wherein the upper substrate and the lower substrate is bonded to each other by a bonding layer that includes a diffusion preventing layer interposed therebetween to prevent diffusion upon the bonding between the upper substrate and the lower substrate.

11. The device set forth in claim 1, wherein between the upper substrate and the lower substrate is disposed a support member for allowing a predetermined space to be defined therebetween so that the sensor section is positioned at the space.

12. The device set forth in claim 1, wherein the lower substrate is formed of silicon nitride.

13. A method of fabricating an RF power detecting device,
forming a sensor section for detecting power of an RF signal on a lower substrate;
patterning a signal transmission line on the underside of an upper substrate; and
coupling the upper substrate and the lower substrate to each other.

14. The method set forth in claim 13, wherein the lower substrate is fabricated by the following steps:
depositing a silicon nitride, a lower electrode layer, a piezoelectric thin film layer and an upper electrode layer in the above order on a silicon lower substrate;
patterning and etching the lower electrode layer, the piezoelectric thin film layer and the upper electrode layer into a given shape.
depositing a movable member on the etched upper electrode layer and then patterning the deposited movable member into a given shape; and
patterning and etching the silicon nitride layer, and then subjecting the silicon substrate surface positioned below the sensor section to etching so as to form a depression on the silicon substrate layer for allowing the sensor section to float thereabove.

15. The method set forth in claim 14, wherein the silicon nitride is deposited on the silicon lower substrate by means of a low-pressure chemical vapor deposition (CVD) method.

16. The method set forth in claim 14, wherein the step of forming the depression is performed by patterning a film for protecting the sensor section and then subjecting the patterned film to anisotropic etching of a silicon wafer using an etching solution.

17. The method set forth in claim 14, wherein the step of forming the depression further comprises the steps of:
depositing and patterning a film for protecting the sensor section on the sensor section, and then vertically etching the silicon substrate region around the sensor section by using anisotropic dry etching of a silicon wafer; and
subjecting the silicon substrate to anisotropic wet etching of a silicon wafer by using an etching solution to form the depression on the silicon substrate surface positioned below the sensor section, so that the sensor section can float above the depression.

18. The method set forth in claim 14, wherein the step of forming the depression further comprises the steps of:
depositing and patterning a film for protecting the sensor section on the sensor section, and then vertically etching the silicon substrate region around the sensor section by using anisotropic dry etching of a silicon wafer; and
subjecting the silicon substrate to isotropic dry etching of a silicon wafer by using an etching solution to form the depression on the silicon substrate surface positioned below the sensor section, so that the sensor section can float above the depression.

19. The method set forth in claim 18, wherein the isotropic etching method includes isotropic etching using XeF₂ gas or isotropic etching using SF₆ gas.

20. The method set forth in claim 13, wherein the upper substrate is fabricated by the following steps:
forming a connection hole for connecting a signal transmission line, a ground line, and the lower electrode of the sensor section to an external circuit therethrough, on a silicon substrate, and then filling the connection hole;
forming, on the silicon substrate, the transmission line for transmitting a signal input from the outside therethrough and an electrode pad for allowing the upper substrate and the lower electrode of the sensor section to be bonded to each other; and
forming and patterning a support member and a bonding layer on the silicon substrate.

21. The method set forth in claim 20, wherein in case of the silicon wafer, the connection hole is formed on the silicon wafer by means of anisotropic wet or dry etching.

22. The method set forth in claim 20, wherein in case of the glass wafer, the connection hole is formed on the glass wafer by means of sand blaster or laser cutting.

23. The method set forth in claim 20, wherein the signal transmission line is formed by means of electroplating or metal thin film deposition.

24. The method set forth in claim 20, wherein the bonding layer is formed of at least one selected from the group consisting of gold, gold-tin alloy, and tin.

25. The method set forth in claim 20, wherein around the bonding layer is formed a diffusion preventing film for preventing diffusion of substance used as bonding material toward the electrodes upon the bonding between the upper and lower substrates.
